(19) United States
(12) Patent Application Publication
(10) Pub. No.: US 2021/0064368 A1
(43) Pub. Date: Mar. 4, 2021

(54) COMMAND TRACKING

(71) Applicant: Micron Technology, Inc., Boise, ID (US)

(72) Inventors: Bruce Dunlop, Bloomington, MN (US); Gary J. Lucas, Somerset, WI (US); Edward C. McGlaughlin, Minneapolis, MN (US)

(21) Appl. No.: 16/554,263

(22) Filed: Aug. 28, 2019

(51) Int. Cl. G06F 9/30; G06F 9/48; G06F 16/903

(52) U.S. Cl. CPC G06F 9/3004; G06F 16/90339; G06F 9/4881

(57) ABSTRACT

An apparatus includes a memory device and command component coupled to the memory component. The command component can be configured to receive commands associated with accessing a physical address in the memory device. The command component can be further configured to track which of the received commands are active, wherein an active command is a command that is ready to be executed and track which of the received commands are pending, wherein a pending command is a command that is waiting for a previously received command associated with a same physical address to be executed. In response to the previously received command being associated with the same physical address being executed, the command component is configured to convert the pending command to an active command.

### TECHNICAL FIELD

Embodiments of the disclosure relate generally to memory sub-systems, and more specifically, relate to command tracking.

### BACKGROUND

A memory sub-system can include one or more memory components that store data. The memory components can be, for example, non-volatile memory components and volatile memory components. In general, a host system can utilize a memory sub-system to store data at the memory components and to retrieve data from the memory components.

### BRIEF DESCRIPTION OF THE DRAWINGS

The present disclosure will be understood more fully from the detailed description given below and from the accompanying drawings of various embodiments of the disclosure.

FIG. 1 illustrates an example computing environment that includes a memory sub-system in accordance with some embodiments of the present disclosure.

FIG. 2 illustrates an example of a command pipeline associated with command tracking in accordance with some embodiments of the present disclosure.

FIG. 3 is a flow diagram of an example flow chart corresponding to a method for using a command component in accordance with some embodiments of the present disclosure.

FIG. 4 is a flow diagram of an example method for command tracking in accordance with some embodiments of the present disclosure.

FIG. 5 is a block diagram of an example computer system in which embodiments of the present disclosure may operate.

### DETAILED DESCRIPTION

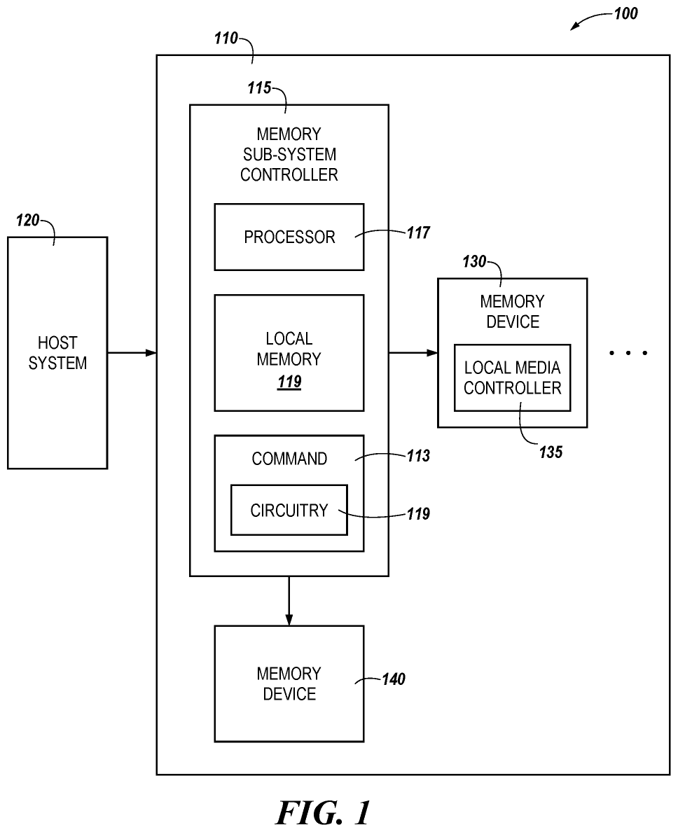

Aspects of the present disclosure are directed to memory sub-systems that include command tracking. A memory sub-system can be a storage device, a memory module, or a hybrid of a storage device and memory module. Examples of storage devices and memory modules are described below in conjunction with FIG. 1. In general, a host system can utilize a memory sub-system that includes one or more memory components, such as memory devices that store data. The host system can provide data to be stored at the memory sub-system and can request data to be retrieved from the memory sub-system.

The memory components can include non-volatile memory devices that store data from the host system. A non-volatile memory device is a package of one or more dice. The dice in the packages can be assigned to one or more channels for communicating with a memory sub-system controller. The non-volatile memory devices include cells (i.e., electronic circuits that store information), that are grouped into pages to store bits of data. The non-volatile memory devices can include three-dimensional cross-point (“3D cross-point”) memory devices that are a cross-point array of non-volatile memory that can perform bit storage based on a change of bulk resistance, in conjunction with a stackable cross-gridded data access array. Such non-volatile memory devices can group pages across dice and channels to form management units (MUs). A MU can include user data and corresponding metadata. A memory sub-system controller can send and receive user data and corresponding metadata as management units to and from memory devices. Another example of a non-volatile memory device is a negative-and (NAND) memory device. With NAND type memory, pages can be grouped to form blocks. Other examples of non-volatile memory devices are described below in conjunction with FIG. 1.

The host system can send access requests (e.g., write command, read command) to the memory sub-system, such as to store data on a memory device at the memory sub-system and to read data from the memory device on the memory sub-system. The data to be read or written, as specified by a host request, is hereinafter referred to as “host data”. A host request can include logical address information (e.g., logical block address (LBA), namespace) for the host data, which is the location the host system associates with the host data. The logical address information (e.g., LBA, namespace) can be part of metadata for the host data.

The memory sub-system can map the logical address information to a physical address (e.g., physical MU address, physical block address) associated with one or more memory devices on the memory sub-system, and write host data to and/or read host data from the physical address.

Memory sub-systems (e.g., SSDs) can include various control circuitry, which can track commands and/or access to physical addresses associated with a memory device. In some conventional approaches, access to particular physical address locations may not be tracked and the order of the accesses can overlap or be too close in time, resulting in incorrect data being accessed and incorrect data being stored back to the memory device(s). For example, a host may access a physical location in a memory device and firmware (e.g., of a memory sub-system controller) may make a subsequent request to access the same location of the memory device so close in time that the access by the host is either still occurring or has just occurred and the memory device may have some lagging effects from the access that may affect the access of the firmware. Likewise, the host may access the memory device and be storing intermediate results of processing back to the memory while the firmware is intending to access the result of the processing by the host even though the processing has not finalized. These scenarios can result in errors in data and intermediate results being treated as finalized results. As an example, a host can be accessing data to perform a number of read operations, write operations, analytical operations, etc. on the data and the finalized data for such operations can be in error due to overlapping data access. As an example, firmware can be accessing the data to refresh the data, perform a number of clock cycles operations, etc. and be expecting to refresh or perform operations on finalized data.

As described below, in order to avoid overlapping access to the same data at a same physical location in a memory device, a command and its associated address can be tracked and subsequent attempts to access the same physical address can be prevented if the initial access has not completed. For example, a host can request access to a particular physical address to execute a command (such as a read operation of data stored in the first physical address). A command component can track the particular physical address in an execution queue and mark the command entry associated with that particular physical address as “active.” An active designation can indicate that a request to access data at the particular physical address has been received and sent on to a memory device where the data is stored. Once the command has been executed on the data at the particular physical address, a response indicating that the command has been executed can be sent to the command component and the “active” status of the command entry associated with the particular physical address can be removed from the execution queue and/or the command entry itself can be removed from the execution queue. Subsequent requests to access data at the particular physical address can then be allowed.

If a subsequent request to access data at the particular physical address is received at the command component while the command entry of the first request is still “active,” the command component can compare the physical address of the subsequent request to physical addresses in the execution queue (which would result in a match of the physical address of the subsequent request and the particular physical address of the initial request). Since there is already an “active” status for a command at that physical address, the subsequent request can be marked as “pending,” can be entered into the execution queue, and is linked with the previous command entry associated with the particular physical address entry. Once the command component has received a response indicating that the initial command has been executed, the initial command entry can be cleared from the execution queue and the subsequent command entry (due to the link in the execution queue) can be sent to the memory device for execution. After each execution of a command, the execution queue can be searched for a link to a subsequent command entry to be executed (which would include any requests to execute a command associated with a same physical address that has been received while an already received command instruction is being processed first).

In this way, while commands are listed as “pending” and waiting for previously received commands to be executed, commands that are subsequently received but associated with a different physical address in the memory device can be executed until a next linked command is allowed to be executed. The ordering of the command executions can be time-based until a physical address matches, in which case the timing can be reordered based on confirmation of executions of commands associated with the same physical addresses, as described above.

FIG. 1 illustrates an example computing environment 100 that includes a memory sub-system 110 in accordance with some embodiments of the present disclosure. The memory sub-system 110 can include media, such as one or more volatile memory devices (e.g., memory device 140), one or more non-volatile memory devices (e.g., memory device 130), or a combination of such.

A memory sub-system 110 can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, and a hard disk drive (HDD). Examples of memory modules include a dual in-line memory module (DIMM), a small outline DIMM (SO-DIMM), and a non-volatile dual in-line memory module (NVDIMM).

The computing environment 100 can include a host system 120 that is coupled to one or more memory sub-systems 110. In some embodiments, the host system 120 is coupled to different types of memory sub-system 110. FIG. 1 illustrates one example of a host system 120 coupled to one memory sub-system 110. The host system 120 uses the memory sub-system 110, for example, to write data to the memory sub-system 110 and read data from the memory sub-system 110. As used herein, “coupled to” generally refers to a connection between components, which can be an indirect communicative connection or direct communicative connection (e.g., without intervening components), whether wired or wireless, including connections such as electrical, optical, magnetic, etc.

The host system 120 can be a computing device such as a desktop computer, laptop computer, network server, mobile device, a vehicle (e.g., airplane, drone, train, automobile, or other conveyance), internet-of-things enabled device, embedded computer (e.g., one included in a vehicle, industrial equipment, or a networked commercial device), or such computing device that includes a memory and a processing device. The host system 120 can be coupled to the memory sub-system 110 via a physical host interface. Examples of a physical host interface include, but are not limited to, a serial advanced technology attachment (SATA) interface, a peripheral component interconnect express (PCIe) interface, universal serial bus (USB) interface, Fibre Channel, Serial Attached SCSI (SAS), etc. The physical host interface can be used to transmit data between the host system 120 and the memory sub-system 110. The host system 120 can further utilize an NVM Express (NVMe) interface to access the memory components (e.g., memory devices 130) when the memory sub-system 110 is coupled with the host system 120 by the PCIe interface. The physical host interface can provide an interface for passing control, address, data, and other signals between the memory sub-system 110 and the host system 120.

The memory devices can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include negative-and (NAND) type flash memory and write-in-place memory, such as three-dimensional cross-point (“3D cross-point”) memory. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased.

Although non-volatile memory devices such as 3D cross-point type and NAND type memory are described, the memory device 130 can be based on any other type of non-volatile memory, such as read-only memory (ROM), phase change memory (PCM), self-selecting memory, other chalcogenide based memories, ferroelectric random access memory (FeRAM), magneto random access memory (MRAM), negative-or (NOR) flash memory, and electrically erasable programmable read-only memory (EEPROM).

One type of memory cell, for example, single level cells (SLC) can store one bit per cell. Other types of memory cells, such as multi-level cells (MLCs), triple level cells (TLCs), and quad-level cells (QLCs), can store multiple bits per cell. In some embodiments, each of the memory devices 130 can include one or more arrays of memory cells such as SLCs, MLCs, TLCs, QLCs, or any combination of such. In some embodiments, a particular memory device can include an SLC portion, and an MLC portion, a TLC portion, or a QLC portion of memory cells. The memory cells of the memory devices 130 can be grouped as pages or codewords that can refer to a logical unit of the memory device used to store data. With some types of memory (e.g., NAND), pages can be grouped to form blocks. Some types of memory, such as 3D cross-point, can group pages across dice and channels to form management units (MUs).

The memory sub-system controller 115 (or controller 115 for simplicity) can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processor (processing device) 117 configured to execute instructions stored in local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, etc. The local memory 119 can also include read-only memory (ROM) for storing micro-code, for example. While the example memory sub-system 110 in FIG. 1 has been illustrated as including the memory sub-system controller 115, in another embodiment of the present disclosure, a memory sub-system 110 may not include a memory sub-system controller 115, and may instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory devices 130. The memory sub-system controller 115 can be responsible for other operations such as wear leveling operations, garbage collection operations, error detection and error-correcting code (ECC) operations, encryption operations, caching operations, and address translations between a logical address (e.g., logical block address (LBA), namespace) and a physical address (e.g., physical MU address, physical block address) that are associated with the memory devices 130. The memory sub-system controller 115 can further include host interface circuitry to communicate with the host system 120 via the physical host interface. The host interface circuitry can convert the commands received from the host system into command instructions to access the memory devices 130 as well as convert responses associated with the memory devices 130 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory devices 130.

In some embodiments, the memory devices 130 include a local media controller 135 that operates in conjunction with memory sub-system controller 115 to execute operations on one or more memory cells of the memory devices 130. An external controller (e.g., memory sub-system controller 115) can externally manage the memory device 130 (e.g., perform media management operations on the memory device 130). In some embodiments, a memory device 130 is a managed memory device, which is a raw memory device combined with a local controller (e.g., local controller 135) for media management within the same memory device package. An example of a managed memory device is a managed NAND (MNAND) device.

The memory sub-system controller 115 includes a command component 113 that can be configured to track physical addresses of memory associated with command instructions for execution. The command component 113 can enter a command and its associated physical address into an execution queue and indicate in the entry whether the command is active (indicating the associated command is being sent to the memory device for execution), pending (indicating that the associated command is waiting in the execution queue until permission is granted or the command is allowed to be sent on for execution), and/or clear the command entry from the execution queue upon completion of the associated command. The indications can include setting a bit, setting a flag, or another indicator that can be referenced. As shown in FIG. 1, the command component 113 can include various circuitry 119 to facilitate the tracking of commands and their associated physical addresses associated with the commands. As an example, the circuitry 119 can include a special purpose circuitry in the form of an ASIC, FPGA, state machine, and/or other logic circuitry that can allow the command component 113 to track and/or monitor commands and corresponding physical addresses.

In one embodiment, the command component 113 includes a content-addressable memory (CAM) component. In a CAM, search data can be compared against a table of stored data whereby an address of matching data can be returned. In this case, entries in the CAM can be searched with a “hit” indicating that a command to a particular address already exists in the CAM (e.g., the physical address to which an incoming command is directed matches a physical address of a command already in the CAM) and a “miss” indicating that a command to the particular address does not already exist in the CAM (e.g., the physical address to which an incoming command is directed does not match a physical address of a command already in the CAM). As described further herein, in various embodiments, a CAM miss results in the incoming command being marked as “active” (e.g., ready for sending to the memory device for execution), and a CAM hit results in the incoming command being marked as “pending” and a delay being introduced to prevent the status of the pending command from being changed to active until a particular time period after the prior active command to the same address is complete.

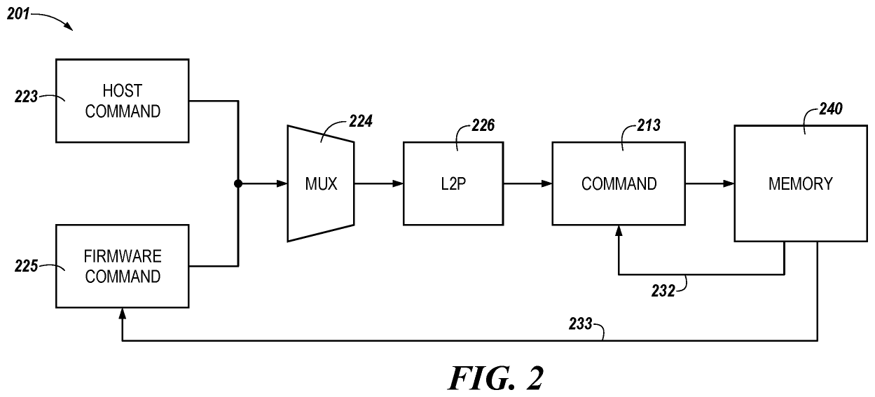

As described in more detail in connection with FIG. 2, the data can be transferred to the command circuitry 119 prior to execution of multiple commands in order to verify that a physical address location in memory is not being targeted by another command. For example, the command circuitry 119 can be used to track and/or monitor execution of the multiple commands by maintaining a list of received commands and whether the commands are pending or active, and can clear a command entry when that command has been executed. In contrast to approaches in which execution of a command is not blocked even though another command that is associated with the same physical address may not have completed execution, the blocking of access to a physical address, as is described below, can be used to prevent overlap of more than one command associated with a same physical address prior to completion of execution of at least one of the commands. Therefore, only one command to a particular physical address is executed at a time, with a next pending command being held (or blocked) until a response from the memory returns a command ID associated with a command that has bene executed at the particular physical address.

FIG. 2 illustrates an example of a command pipeline 201 associated with command tracking in accordance with some embodiments of the present disclosure. The pipeline 201 can include media, such as memory device 240 (e.g., a memory component), which can be analogous to the memory device 140 illustrated in FIG. 1. In addition, the command pipeline 201 can include a command component 213, which can be analogous to the command component 113 illustrated in FIG. 1. The command component 213 can receive a host command (e.g., a command received from a host) 223 and/or a firmware command (e.g., firmware that can be executed to perform functions associated with a firmware command) 225 through a multiplexer (“mux”) 224 and a logical to physical (“L2P”) component 226. As an example, the host (e.g., host 120) can send a request, including host command 223, to perform a read operation on data stored in the memory 240. The host can send a request, including host command 223, to perform a write operation on data stored in the memory 240. As an example, the firmware can be executed to send a request, including firmware command 225, to refresh data stored in the memory 240. The firmware can be executed to send a request, including the firmware command 225, to perform an operation associated with a particular clock cycle on data stored in the memory 240. In the event that both the host command 223 and the firmware command 225 are received in tandem, the memory 240 may be accessed so close in time that an affect on the data stored in the memory may occur, altering a value stored in the data and/or creating errors in the data and in subsequent operations performed on the data.

The host can send or the firmware can be executed to send a request, including host command 223 or firmware command 225, to perform an operation on the data in memory 240 by sending the request through the mux 224. A simple round-robin priority may be performed if a command is received at the same time from the host and or through the firmware. The request stream of commands from one interface (e.g., host 120 or firmware) can be processed in a first-in-first-out (FIFO) order and also the requests from either of the interfaces can be processed as if a single stream in FIFO order in relation to each other. In some embodiments, a component can be between the mux 224 and an L2P component 226 and can split commands with multiple physical address locations identified into single commands identifying single physical address locations. The L2P component 226 maps logical address to physical addresses.

The sent request can be initially sent to a L2P component 226 in order to convert data associated with a logical address to be associated with a physical address. As an example, the host command 223 can be sent to the mux 224 and can be associated with a logical address in the memory 240 and the L2P component 226 can associate the data with a physical address. In one example, the address associated with execution of the firmware command 225 can already be a physical address. The firmware command 225 can be sent from the L2P component 226 to the command component 213 using a logical to physical conversion. In some embodiments, a split component (not illustrated) can be between the command component 213 and the memory 240. The split component can split commands that identify multiple channels and/or dies into single commands identifying a single channel and/or die. In this example, the command component 213 can send a command to execute to the split component first and the split component would then transfer the processed command to the memory 240 for execution.

As a command is received from either the host or through execution of the firmware at the command component 213, the command component 213 determines whether a physical address associated with the command is also associated with an already received command. An execution queue in the command component 213 can list entries that indicate all commands that have been received along with their corresponding physical addresses. Each of the entries in the execution queue can indicate whether the commands are active (indicating the commands have been sent to memory for execution) or pending (indicating that the commands are delayed or withheld from being sent to the memory until a response indicating that all previously received commands associated with the same physical address have been executed).

In order to avoid an overlap of access to the memory 240, the command component 213 can prevent access to data stored in a same physical address of memory 240 by one command as other commands may be used to already access that same physical address until the initial access has been completed. As an example, a command can be received at the command component 213 that is associated with a particular physical address. The particular physical address can be compared to the entries in the execution queue to determine whether that particular physical address is already in the execution queue and associated with a previously received command. An entry is generated in the execution queue for the received command and the entry is indicated as pending if there is an entry of a previously received command that is associated with the particular physical address. In the case of a pending command, a link is entered into the active command entry such that when the active command is executed, the link is accessed and directs the command component 213 to process the subsequently received command associated with the same physical address next.

Each entry in the execution queue includes a command identification (ID) that is used to identify a particular entry in the queue, the particular physical address that is associated with the received command, and a status of the entry (which in this example, would be pending). In one example, there may have been a previously received command but if the previously received command has been executed and cleared from the execution queue, the received command could be indicated as active and sent for execution. If the particular physical address does not match another physical address associated with the commands in the execution queue, the entry for the received command would be indicated as active and the command would be sent to the memory for execution.

In the event that a previously received command is active and yet to be executed, a pending command entry can be delayed or held until a response, illustrated as arrow 232, is received from the memory 240 indicating that the active command has been executed. Once the response 232 is received, the link in the active command entry (of the previously received command which has now been executed) can direct the command component 213 to process the received command next. Further, a response, illustrated as arrow 233, can be sent to a host or to additional firmware to be executed that verifies that a command has been executed. The active command entry (of the previously received command) can be cleared and the pending command entry (of the received command) can be updated to an active command entry. However, if there was an intermediate command sent subsequent to the previously received command but prior to the received command, the received command would be delayed until this intermediate command was executed. In this example, the previously received command entry would link to the intermediate command entry and the intermediate command entry would be linked to the received command entry. In this way, an order of commands that are associated with a same physical address can be tracked in order to avoid duplicate access of the physical address.

In the event that a command is received that corresponds to a different physical address and does not correspond to another physical address in the execution queue, the command can be indicated as active and executed in the regular FIFO fashion (e.g., in the order of time it was received). In this way, commands are delayed in relation to other commands with a same physical address, but commands with different physical addresses are executed in the order of time they were received, absent the different physical address already being in the execution queue and associated with another command.

In some embodiments, a write blocking FIFO can be used for forced write (FW) commands. The logic of the write blocking FIFO can insure that a write that is blocked (marked as pending because of a conflict with an active command) will also cause subsequent writes to be blocked in FIFO order behind it. This can align all FW write commands to be forwarded with the same order as the write data arriving from the host (e.g., host command 223) or as firmware (e.g., firmware command 225) because the FW write data buffer may only provide FIFO accessing and not random accessing.

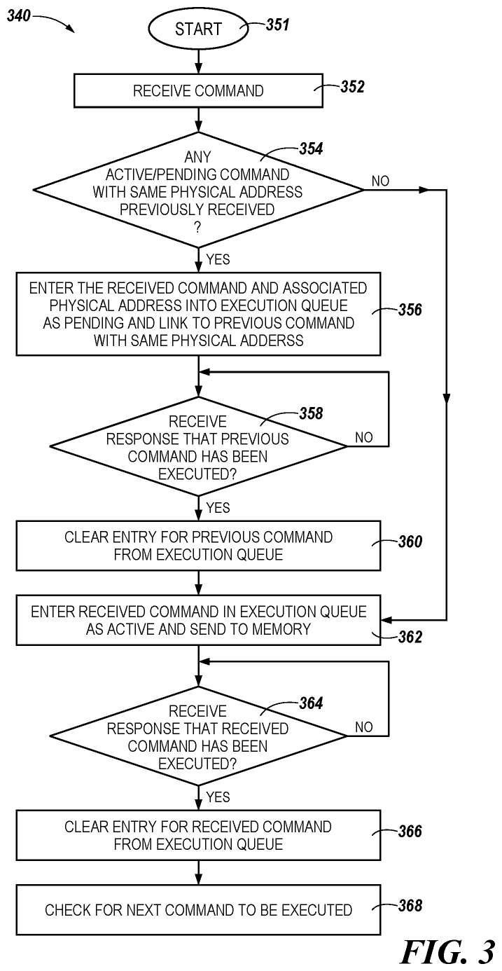

FIG. 3 is a flow diagram of an example flow chart 340 corresponding to a method for using a command component in accordance with some embodiments of the present disclosure. At 351, the flow chart 340 can start and, at 352, can include receiving a command. The command can be received at a command component (such as command component 113, 213 in FIGS. 1 and 2, respectively). At 354, in response to receiving the command, the method 340 can include determining whether another active or pending command with a same physical address has been previously received and are listed in an execution queue. In one example, the execution queue can include entry locations for the listing of 128 commands. As the commands are received, each command can be entered into the execution queue at one of these entry locations. Each of the entry locations can have a corresponding command identification (ID) that identifies a particular command in the command component. The determination can include comparing the received command and associated physical address to each of the entries in the execution queue. At 362, the method 340 can include, in response to no entries in the execution queue matching the received command (indicating no commands in the execution queue are associated with a same physical address as the received command), the received command and its associated physical address can be entered into the execution queue as active and sent to the memory for execution.

At 356, the method 340 can include, in response to an entry in the execution queue matching the received command (indicating a previously received command is associated with a same physical address in the memory as the currently received command), the received command and its associated physical address is entered into the execution queue as pending and the received command is linked to the previous command that matched. In this way, a pending entry in the execution queue indicates that a command has been received but is being delayed until the previously received command (with a same physical address) has been executed. In some embodiments, the entries that are all associated with a same physical address can be ordered based on time of receival as well to maintain an order of the executions of commands (which will also be maintained based on the links between the commands with a same physical address).

At 358, a determination is made regarding whether the previous command has been executed, If the previous command has been executed, the entry for the previous command is cleared from the execution queue, as shown at 360. The received command can be delayed and remain pending until a response is received from the memory indicating that the previously received command has been executed. The response from the memory can include the command ID associated with the entry so that the entry of the command that was executed can be located in the execution queue and cleared. At 362, in response to clearing the previously received command entry, the received command entry can be entered as an active command and be sent to the memory for execution.

In response to none of the entries in the execution queue matching the received command (indicating previously received commands are associated with different physical addresses in the memory), as shown at 362 of the method 340, the received command and its associated physical address is entered into the execution queue as active and the received command is sent to the memory for execution. The received command can also be flagged as an “oldest” entry in the execution queue to maintain an order in time of the commands.

At 364, a determination whether a response is received from the memory indicating that the received command has been executed can be made. The received command can remain as an active entry in the execution queue until a response is received from the memory indicating that the received command has been executed. At 366, when the response indicating the received command has been executed is received, the entry in the execution queue corresponding to the previously received command can be cleared. At 368, in response to clearing the received command entry, the execution queue can be checked for a next command to be executed.

If, while the method of flowchart 340 described above is being performed, an additional command associated with the same physical address is received (subsequent to receiving the received command but prior to execution of the received command), the additional command would have been linked to the received command and indicated as pending. The checking of the execution queue for the next command would identify the link to the additional command and the additional command would be changed to an active command and sent to the memory for execution. However, if subsequent commands associated with different physical addresses are received while performing the method of flow chart 340, the check of the execution queue would identify the subsequent commands to be sent to the memory for execution in the order that the subsequent commands were received in time. For instance, if one of the subsequent commands were received subsequent to receiving the received command but prior to execution of the previously received command, the one of the subsequent commands would be sent to the memory for execution (since the received command would still be a pending command).

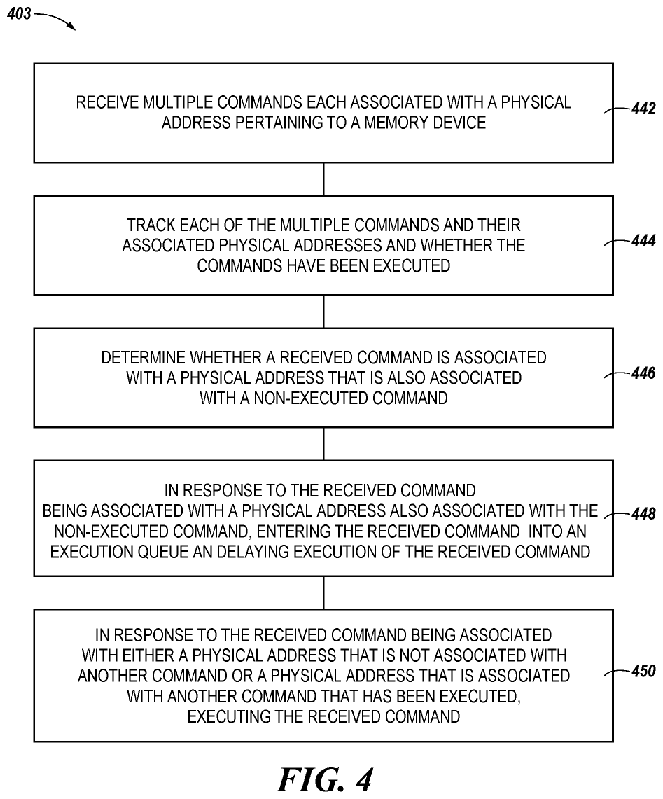

FIG. 4 is a flow diagram of an example method 403 corresponding to a command component in accordance with some embodiments of the present disclosure. The method 403 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 403 is performed by the command component 113 of FIG. 1, and/or the command component 213 of FIG. 2. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At block 442, the method 403 includes receiving, by a processing device (such as command component 113, 213 in FIGS. 1 and 2), multiple commands each associated with a physical address pertaining to a memory device. In some embodiments, at least two of the commands have a same physical address and at least one of the two commands are delayed, as is described above. In some embodiments, at least two of the commands have different physical addresses and these at least two commands are executed in the order of time that they are received.

At block 444, the method 403 includes tracking, by the processing device, each of the multiple commands and their associated physical addresses and whether the commands have been executed. The tracking of the commands can be facilitated by an execution queue within a compute component. The execution queue can indicate whether each of the commands are active (meaning the commands are sent for execution) or pending (meaning the commands are being delayed until a response is received from the memory indicating execution of another command, as is described above).

At block 446, the method 403 includes determining whether a received command is associated with a physical address that is also associated with a non-executed command. At block 448, the method 403 includes, in response to the received command being associated with a physical address also associated with the non-executed command, entering the received command into an execution queue and delaying execution of the received command. In response to determining that the command is associated with a physical address also associated with a non-executed command, and the non-executed command was previously received, the received command is indicated as pending and delayed. In this way, the received command is blocked from accessing the physical address in the memory while the previously received command may be accessing that physical address.

At block 450, the method 403 includes, in response to the received command being associated with either a physical address that is not associated with another command or a physical address that is associated with another command that has been executed, executing the received command. The received command not associated with another command can be indicated as an active command in the execution queue. In response to the memory sending a response to the command component indicating the active command has been executed, the entry in the execution queue can be cleared and the next command in line (either with a same physical address and marked by a link to that command or a command that was received next in order in time) can be indicated as active and sent for execution.

In some embodiments of the present disclosure, the method 403 further includes designating a received command as an active command in response to the received command being associated with a physical address that is not associated with another command. The method 403 further includes designating the received command as a pending command in response to the received command being associated with a physical address that is associated with an active command, wherein the active command is a command that has not been executed. The method 403 further includes, in response to designating the received command as the pending command, linking the active command with the pending command. The linking can direct the command component to execute the pending command in response to the active command being executed. The method 403 further includes, in response to the active command being executed, designating the pending command as a next active command and sending the next active command to the memory device to be executed.

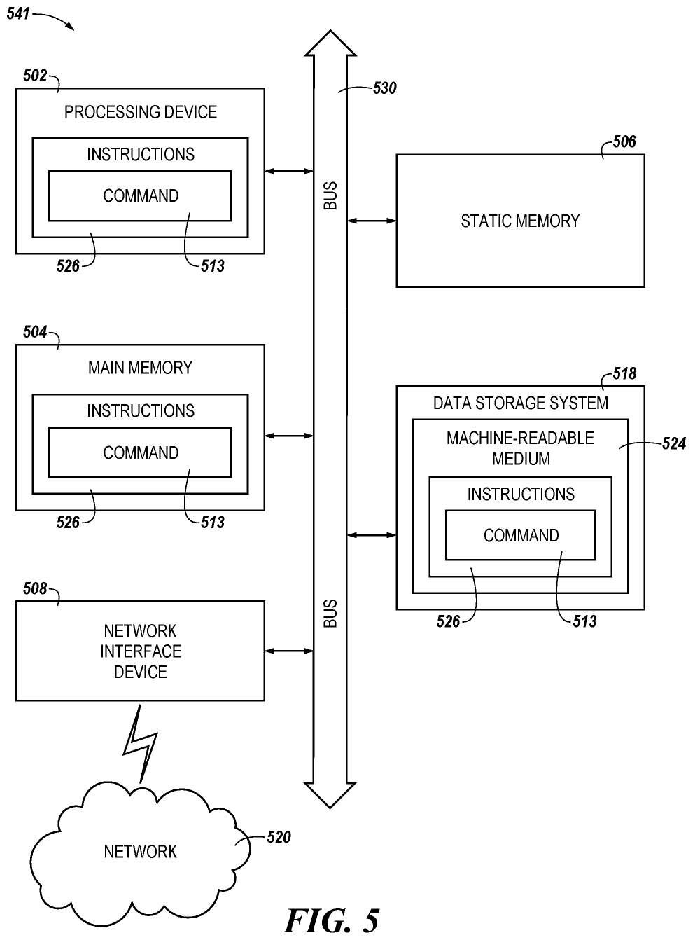

FIG. 5 illustrates an example machine of a computer system 541 within which a set of instructions, for causing the machine to perform one or more of the methodologies discussed herein, can be executed. In some embodiments, the computer system 541 can correspond to a host system (e.g., the host system 120 of FIG. 1) that includes, is coupled to, or utilizes a memory sub-system (e.g., the memory sub-system 110 of FIG. 1) or can be used to perform the operations of a controller (e.g., to execute an operating system to perform operations corresponding to the command component 113 of FIG. 1). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or another machine capable of executing a set of instructions (sequential or otherwise) that specify actions to be taken by that machine. Further, while a single machine is illustrated, the term “machine” shall also be taken to include a collection of machines that individually or jointly execute a set (or multiple sets) of instructions to perform one or more of the methodologies discussed herein.

The example computer system 541 includes a processing device 502, a main memory 604 (e.g., read-only memory (ROM), flash memory, dynamic random access memory (DRAM) such as synchronous DRAM (SDRAM) or Rambus DRAM (RDRAM), etc.), a static memory 506 (e.g., flash memory, static random access memory (SRAM), etc.), and a data storage system 518, which communicate with each other via a bus 530.

The processing device 502 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. The processing device 502 can also be one or more special-purpose processing devices such as an application specific integrated circuit (ASIC), a field programmable gate array (FPGA), a digital signal processor (DSP), network processor, or the like. The processing device 502 is configured to execute instructions 526 for performing the operations and steps discussed herein. The computer system 541 can further include a network interface device 508 to communicate over the network 520.

The data storage system 518 can include a machine-readable storage medium 524 (also known as a computer-readable medium) on which is stored one or more sets of instructions 526 or software embodying one or more of the methodologies or functions described herein. The instructions 526 can also reside, completely or at least partially, within the main memory 504 and/or within the processing device 502 during execution thereof by the computer system 541, the main memory 504 and the processing device 502 also constituting machine-readable storage media. The machine-readable storage medium 524, data storage system 518, and/or main memory 504 can correspond to the memory sub-system 110 of FIG. 1.

In one embodiment, the instructions 526 include instructions to implement functionality corresponding to a compute component (e.g., the compute component 113 of FIG. 1). The instructions can include a command instruction 513 associated with performing operations with a command component (such as command component 113 in FIG. 1). While the machine-readable storage medium 524 is shown in an example embodiment to be a single medium, the term “machine-readable storage medium” should be taken to include a single medium or multiple media that store the one or more sets of instructions. The term “machine-readable storage medium” shall also be taken to include a medium that is capable of storing or encoding a set of instructions for execution by the machine and that cause the machine to perform one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, types of disk including floppy disks, optical disks, CD-ROMs, and magnetic-optical disks, read-only memories (ROMs), random access memories (RAMs), EPROMs, EEPROMs, magnetic or optical cards, or type of media suitable for storing electronic instructions, each coupled to a computer system bus.

The algorithms and displays presented herein are not inherently related to a particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to a particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes a mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

1. An apparatus, comprising:
a memory device; and
a command component coupled to the memory component; and
a component coupled to the command component, wherein the component is configured to split commands with multiple physical address locations identified into single commands identifying single physical address locations;
wherein the command component is configured to:
receive commands each associated with accessing a physical address in the memory component;
track which of the received commands:
are active; and
are pending; and
delay the pending commands associated with a particular physical address until active commands associated with the particular physical address are executed;
wherein, in response to execution of the previously received command associated with the same physical address, the command component is configured to convert the pending command to an active command.

2. The apparatus of claim 1, wherein the command component is configured to:
determine that a previously received command that has not been executed is associated with the particular physical address; and
in response to the determination, place the received command into an execution queue.

3. The apparatus of claim 2, wherein the command component is configured to link the received command to the previously received command.

4. The apparatus of claim 2, wherein the command component is configured to receive an indication that the previously received command has been executed.

5. The apparatus of claim 4, wherein the command component is configured to, in response to receiving the indication, execute the received command.

6. The apparatus of claim 1, wherein the command component is configured to, in response to determining that the particular physical address has no active commands or pending commands that were received previously, executing the received command.

7. The apparatus of claim 1, wherein the command component is configured to associate each command and associated physical address with a command identification (ID).

8. The apparatus of claim 7, wherein the command component is configured to receive a response from the memory component that a particular command has been executed, wherein the response includes a command ID.

9. The apparatus of claim 8, wherein the command component is configured to clear an active command associated with the received command ID.

10. A method, comprising:
receiving, by a processing device, a plurality of commands each associated with a physical address pertaining to a memory device;
splitting those commands of the plurality of commands with multiple physical address locations into single commands identifying single physical locations;
tracking, by a processing device, each of the plurality of commands and their associated physical addresses and whether the commands have been executed;
determining whether a received command is associated with a physical address that is also associated with a non-executed command;
in response to the received command being associated with a physical address also associated with the non-executed command, entering the received command into an execution queue and delaying execution of the received command; and
in response to the received command being associated with either a physical address that is not associated with another command or a physical address that is associated with another command that has been executed, executing the received command.

11. The method of claim 10, comprising:
designating a received command as an active command in response to the received command being associated with a physical address that is not associated with another command;
designating the received command as a pending command in response to the received command being associated with a physical address that is associated with an active command, wherein the active command is a command that has not been executed.

12. The method of claim 11, comprising, in response to designating the received command as the pending command, linking the active command with the pending command.

13. The method of claim 12, wherein, in response to the active command being executed, the pending command is executed based on the linking.

14. The method of claim 13, comprising, in response to the active command being executed, designating the pending command as a next active command and sending the next active command to the memory component to be executed.

15. A system, comprising:
a memory device; and
a processing device coupled to the memory device to perform operations comprising:
receiving commands associated with a physical address pertaining to the memory device;
splitting those commands of the received commands with multiple physical address locations into single commands identifying single physical locations;
tracking which of the received commands are:
pending commands, wherein a pending command indicates that a previously received command is associated with a same physical address as the pending command; or
active commands, wherein an active command indicates that there are no commands with a same physical address to be executed and each of the commands are associated with a command identification (ID) that indicates a location in the command component at which the tracked command is stored;
receiving a response from the memory device with a command ID corresponding to an active command has been executed; and
in response to receiving the response from the memory device, clearing the active command from the location in the command component associated with the command ID.

16. The system of claim 15, further comprising a command content-addressable memory (CAM).

17. The system of claim 16, wherein the CAM is used to order execution of the received commands.

18. The system of claim 16, wherein the CAM is to perform operations comprising:
delaying execution of a pending command associated with a same physical address as an active command; and
executing the delayed command in response to receiving the response indicating that the active command has been executed.

19. The system of claim 18, wherein the CAM is to perform operations further comprising:
linking the delayed pending command to the active command.

20. The system of claim 19, wherein the CAM is to perform operations further comprising:
in response to receiving the response from the memory device, executing the delayed pending command based on the link.
